(19) United States
(12) Patent Application Publication
(10) Pub. No.: US 2023/0389315 A1
(43) Pub. Date: Nov. 30, 2023

(54) SEMICONDUCTOR MEMORY DEVICE AND METHOD OF MANUFACTURING THE SAME

(71) Applicant: SK hynix Inc., Gyeonggi-do (KR)

(72) Inventor: Jae Young OH, Gyeonggi-do (KR)

(21) Appl. No.: 17/990,064

(22) Filed: Nov. 18, 2022

(30) Foreign Application Priority Data
May 26, 2022 (KR) 10-2022-0065014

(51) Int. Cl. H01L 29/76

(52) U.S. Cl. CPC H01L 27/11582

(57) ABSTRACT

Provided herein may be a semiconductor memory device and a method of manufacturing the same. The semiconductor memory device may include a gate stack, and a channel structure disposed in the gate stack, wherein the channel structure may include a channel layer including a first portion penetrating the gate stack and a second portion extending from the first portion to protrude higher than the gate stack, a core insulating layer disposed in a central region of the channel structure, and a barrier layer disposed between the channel layer and the core insulating layer.

### CROSS-REFERENCE TO RELATED APPLICATION

The present application claims priority under 35 U.S.C. § 119(a) to Korean patent application number 10-2022-0065014, filed on May 26, 2022, in the Korean Intellectual Property Office, the entire disclosure of which is incorporated herein by reference.

### BACKGROUND

### Field of Invention

Various embodiments of the present invention disclosure relate generally to a semiconductor memory device and a method of manufacturing the semiconductor memory device and, more particularly, to a three-dimensional (3D) semiconductor memory device and a method of manufacturing the 3D semiconductor memory device.

### Description of Related Art

A nonvolatile memory device retains stored data even when the supply of power is interrupted. Recently, as two-dimensional (2D) nonvolatile memory devices in which memory cells are formed on a substrate in a single layer is reaching its physical scaling limit (e.g., degree of integration), three-dimensional (3D) nonvolatile memory devices including memory cells vertically stacked on a substrate have been proposed.

Such 3D nonvolatile memory devices may include interlayer insulating layers and gate electrodes that are alternately stacked on top of one another, and channel layers passing through the interlayer insulating layers and the gate electrodes, with memory cells stacked along the channel layers. However, for improving the operational reliability of such 3D nonvolatile memory devices further improvements in their structures and manufacturing methods are needed.

### SUMMARY

Various embodiments of the present invention disclosure are directed to a semiconductor memory device, which enables a manufacturing process thereof to be facilitated and has a stable structure and improved characteristics, and a method of manufacturing the semiconductor memory device.

An embodiment of the present invention disclosure may provide for a semiconductor memory device. The semiconductor memory device may include a gate stack and a channel structure disposed in the gate stack, wherein the channel structure includes a channel layer including a first portion penetrating the gate stack and a second portion extending from the first portion to protrude higher than the gate stack, a core insulating layer disposed in a central region of the channel structure, and a barrier layer disposed between the channel layer and the core insulating layer.

An embodiment of the present invention disclosure may provide for a method of manufacturing a semiconductor memory device. The method may include forming a gate stack on a substrate, forming an opening that passes through the gate stack and extends into the substrate, forming a memory layer in the opening, forming a channel layer in the memory layer, forming a barrier layer in the channel layer, forming a core insulating layer in the barrier layer, removing the substrate such that the channel layer includes a first portion penetrating the gate stack and a second portion extending from the first portion to protrude higher than the gate stack, and implanting a conductive impurity into the second portion of the channel layer.

An embodiment of the present invention disclosure may provide for a method of manufacturing a semiconductor memory device. The method may include forming a gate stack on a substrate, forming a first opening that passes through the gate stack and extends into the substrate, forming a memory layer in the first opening, forming a channel layer in the memory layer, the channel layer including a first portion penetrating the gate stack and a second portion extending from the first portion to protrude higher than the gate stack, forming a first core insulating layer in the channel layer, removing respective portions of the substrate, the memory layer, and the channel layer such that the first core insulating layer is exposed, forming a second opening by removing the first core insulating layer, forming a barrier layer along a surface of the second opening, and implanting a conductive impurity into the second portion of the channel layer.

These and other features and advantages of the present invention will become apparent to those with ordinary skill in the art from the following detailed description of embodiments in conjunction with the following drawings.

### BRIEF DESCRIPTION OF THE DRAWINGS

FIGS. 1A and 1B are schematic sectional views illustrating the structure of a semiconductor memory device according to an embodiment of the present invention disclosure.

FIGS. 2A and 2B are schematic sectional views illustrating the structure of a semiconductor memory device according to an embodiment of the present invention disclosure.

FIGS. 3A to 3E are schematic sectional views illustrating a method of manufacturing a semiconductor memory device according to an embodiment of the present invention disclosure.

FIGS. 4A to 4E are schematic sectional views illustrating a method of manufacturing a semiconductor memory device according to an embodiment of the present invention disclosure.

FIG. 5 is a simplified block diagram illustrating the configuration of a memory system according to an embodiment of the present invention disclosure.

FIG. 6 is a simplified block diagram illustrating the configuration of a computing system according to an embodiment of the present invention disclosure.

### DETAILED DESCRIPTION

In embodiments conforming to the concept of the present invention disclosure as disclosed in the present specification or application, specific structural or functional descriptions are exemplified to describe embodiments conforming to the concept of the present invention disclosure. However, embodiments conforming to the concept of the present invention disclosure are not construed as being only limited to the described embodiments, and other embodiment or modifications thereof may also be implemented in various forms without departing from the scope of the invention.

In embodiments of the present invention disclosure, it will be understood that, although the terms “first” and “second” may be used herein to describe various elements, these elements should not be limited by these terms. The terms are used to distinguish one element from other elements. For instance, a first element discussed below could be termed a second element without departing from the teachings of the present invention disclosure. Similarly, the second element could also be termed the first element.

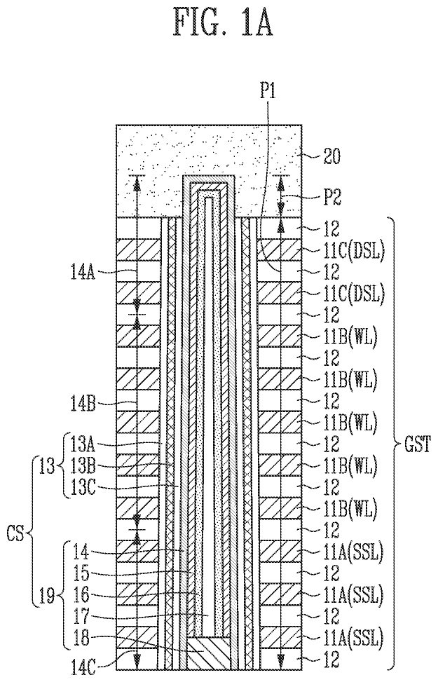

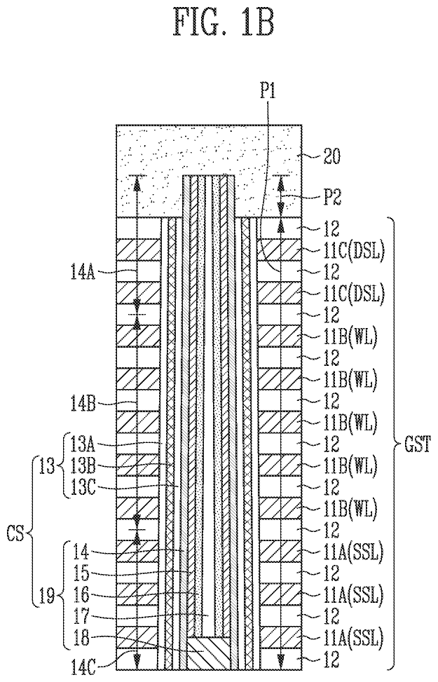

FIGS. 1A and 1B are schematic sectional views illustrating the structure of a semiconductor memory device according to an embodiment of the present invention disclosure.

Referring to FIGS. 1A and 1B, the semiconductor memory device according to an embodiment of the present invention disclosure may include a gate stack GST, a channel structure 19 penetrating the gate stack GST, and a memory layer 13 between the channel structure 19 and the gate stack GST. A cell string CS of the semiconductor memory device may be defined along the channel structure 19. The semiconductor memory device may further include a doped semiconductor layer 20.

The doped semiconductor layer 20 may be formed over the respective tops of the gate stack CST, the channel structure 19, and the memory layer 13. The doped semiconductor layer 20 may cover the respective tops of the gate stack CST, the channel structure 19, and the memory layer 13.

The gate stack GST may include conductive layers 11A, 11B, and 11C and insulating layers 12, which are alternately stacked. The conductive layers 11A, 11B, and 11C may include first conductive layers 11A, second conductive layers 11B, and third conductive layers 11C. The first conductive layers 11A and the third conductive layers 11C may be select lines. The first conductive layers 11A may be source select lines SSL, and the third conductive layers 11C may be drain select lines DSL. The second conductive layers 11B may be disposed between the first conductive layers 11A and the third conductive layers 11C, and may be word lines WL. The insulating layers 12 may be configured to insulate the stacked conductive layers 11A, 11B, and 11C from each other, and may include an insulating material such as an oxide or a nitride.

The numbers of first conductive layers 11A, second conductive layers 11B, and third conductive layers 11C included in the gate stack GST may be adjusted to various values. The number of first conductive layers 11A and the number of third conductive layers 11C may be equal to or different from each other. In an example, the number of first conductive layers 11A may be greater than the number of third conductive layers 11C.

The channel structure 19 may penetrate the gate stack GST along the stacking direction of the gate stack GST. The channel structure 19 may include a channel layer 14 enclosed by the memory layer 13, and a barrier layer 16, a core Insulating layer 17, and a capping pattern 18, which form a central region of the channel structure 19. The channel structure 19 may further include a liner layer 15 disposed between the channel layer 14 and the barrier layer 16. The liner layer 15 may be configured to insulate the channel layer 14 and the barrier layer 16 from each other, and may include an insulating material such as an oxide or a nitride.

The cell string CS may include at least one source select transistor, memory cells, and at least one drain select transistor, which are connected in series to each other through the channel layer 14 corresponding to the cell string CS. The select transistors may be disposed in regions in which the channel layer 14 and the first and third conductive layers 11A and 11C intersect each other. Source select transistors may be disposed in regions in which the channel layer 14 and the first conductive layers 11A intersect each other. Drain select transistors may be disposed in regions in which the channel layer 14 and the third conductive layers 11C intersect each other. The memory cells may be disposed in regions in which the channel layer 14 and the second conductive layers 11B intersect each other.

The channel layer 14 may have a vertical structure. The channel layer 14 may be used as a channel region for select transistors and memory cells which belong to the cell string CS corresponding to the channel layer 14. The channel layer 14 may be formed of silicon (Si), germanium (Ge) or a combination thereof. In an embodiment, the channel layer 14 may include undoped silicon, and may include a doped region including at least one of n-type impurities and p-type impurities. An erase operation on a memory cell may be performed by decreasing the threshold voltage of the memory cell using a potential difference between a word line WL coupled to the memory cell and the channel layer 14. The erase operation may be performed using a well-erase method or a gate induced drain leakage (GIDL) erase method. In an embodiment, the GIDL erase method may be performed using a gate induced drain leakage (GIDL) current. The GIDL current may be generated in a source select transistor or a drain select transistor. Holes may be supplied to the channel layer 14 using the GIDL current, and may be injected into a data storage layer 13B of the memory cell using a potential difference between the channel layer 14 and the word line WL.

The channel layer 14 may include a first region 14A, a second region 14B, and a third region 14C. Here, the first region 14A may be adjacent to the doped semiconductor layer 20. The third region 14C may be adjacent to the capping pattern 18. The second region 14B may be disposed between the first region 14A and the third region 14C. The first to third regions 14A, 14B, and 14C may be integrally coupled to each other.

The third region 14C may correspond to the source select lines SSL. In other words, the third region 14C may be a channel region for source select transistors. The second region 14B may be a region corresponding to the word lines WL. In other words, the second region 14B may be a channel region for memory cells. The first region 14A may be a region corresponding to the drain select lines DSL. In other words, the first region 14A may be a channel region for drain select transistors.

The channel structure 19 may be coupled to the doped semiconductor layer 20. The channel layer 14 may protrude into the doped semiconductor layer 20. The channel layer 14 may include a first portion P1 penetrating the gate stack GST and a second portion P2 extending from the first portion P1 to protrude higher than the gate stack GST. The second portion P2 of the channel layer 14 may contact the doped semiconductor layer 20.

The barrier layer 16 may be formed on the liner layer 15. The barrier layer 16 may have a single-layer structure or a multi-layer structure. The barrier layer 16 may include a conductive material or an insulating material having a denser film quality than that of the core insulating layer 17. The conductive material of the barrier layer 16 may include a metal nitride, metal or a combination thereof. In an embodiment, the conductive material for the barrier layer 16 may include a titanium nitride (TiN), tungsten (W) or a combination thereof. The present invention disclosure is not limited thereto. When impurities are implanted into the second portion P2 of the channel layer 14, the barrier layer 16 may block the impurities. The insulating material of the barrier layer 16 may include a metal oxide. In an embodiment, the insulating material of the barrier layer 16 may be formed of a titanium oxide (TiO₂), a tungsten oxide (WO₃) or a combination thereof.

When the barrier layer 16 is made of an insulating material, the liner layer 15 may be omitted.

The capping pattern 18 may contact the channel layer 14. The capping pattern 18 may contact the core insulating layer 17. The capping pattern 18 may be formed of silicon (Si), germanium (Ge) or a combination thereof, which includes conductive dopants for junctions. In an embodiment, the capping pattern 18 may be formed of n-type doped silicon. The core insulating layer 17 may be disposed between the capping pattern 18 and the doped semiconductor layer 20.

The memory layer 13 may be formed on a sidewall of the channel layer 14. The memory layer 13 may include a tunnel insulating layer 13C, a data storage layer 13B, and a blocking insulating layer 13A, which are sequentially stacked on the sidewall of the channel layer 14. The data storage layer 13B may be formed of a material layer capable of storing changed data using Fowler-Nordheim tunneling. For this, the data storage layer 13B may be formed of various materials, for example, a nitride layer enabling charge trapping. An embodiment of the present invention disclosure is not limited thereto, and the data storage layer 13B may include a floating gate, a charge trap material, polysilicon, a nitride, a variable resistance material, a phase-change material, nanodots, or the like. The blocking insulating layer 13A may include an oxide layer capable of blocking charges. The tunnel insulating layer 13C may be formed of a silicon oxide layer enabling charge tunneling.

The liner layer 15 and the barrier layer 16 may enclose a sidewall of the core insulating layer 17 between the capping pattern 18 and the doped semiconductor layer 20. The channel layer 14 may be interposed between the memory layer 13 and the liner layer 15, and may extend to enclose a sidewall of the capping pattern 18. A doped region including at least one of n-type impurities and p-type impurities may be formed at both ends of the channel layer 14 adjacent to the capping pattern 18 and the doped semiconductor layer 20.

Referring to FIG. 1A, the channel layer 14, the liner layer 15, and the barrier layer 16 may be interposed between the doped semiconductor layer 20 and the core insulating layer 17. The doped semiconductor layer and the core insulating layer 17 may be spaced apart from each other by the channel layer 14, the liner layer 15, and the barrier layer 16.

Referring to FIG. 1B, the channel layer 14, the liner layer 15, and the barrier layer 16 may extend along the sidewall of the core insulating layer 17. The core insulating layer 17 may have a first surface contacting the doped semiconductor layer 20. Each of the channel layer 14, the liner layer 15, and the barrier layer 16 may be located at substantially the same level as the first surface of the core insulating layer 17.

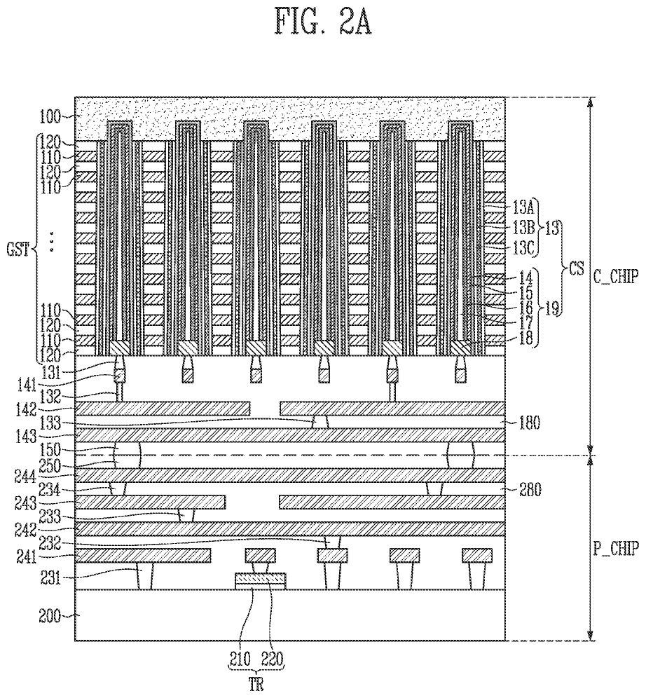

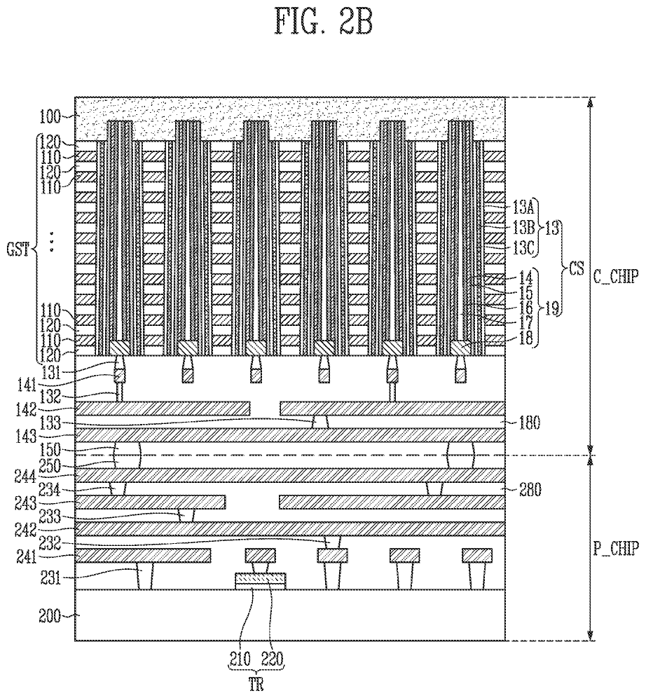

FIGS. 2A and 2B are schematic sectional views illustrating the structure of a semiconductor memory device according to an embodiment of the present invention disclosure.

Referring to FIGS. 2A and 2B, the semiconductor memory device according to an embodiment of the present invention disclosure includes a cell chip C_CHIP and a peripheral circuit chip P_CHIP coupled to the cell chip C_CHIP. The cell chip C_CHIP and the peripheral circuit chip P_CHIP may be coupled to each other. The cell chip C_CHIP may be disposed on the peripheral circuit chip P_CHIP, or alternatively, the peripheral circuit chip P_CHIP may be disposed on the cell chip C_CHIP.

The cell chip C_CHIP may include a doped semiconductor layer 100, a gate stack GST, interconnection structures 131, 132, 133, 141, 142, and 143, first coupling structures 150, channel structures 19 corresponding to cell strings CS, memory layers 13, and a first interlayer insulating layer 180.

The gate stack GST may include conductive layers 110 and insulating layers 120 alternately stacked.

The doped semiconductor layer 100 may be disposed on the gate stack GST.

The channel structures 19 and the memory layers 13 may penetrate the gate stack GST. The gate stack GST, the doped semiconductor layer 100, the channel structures 19, and the memory layers 13 may have the same structure and may be formed of the same material layers as the embodiment described above with reference to FIGS. 1A and 1B. In an embodiment, as illustrated in FIG. 2A, a tunnel insulating layer 13C, a data storage layer 13B, and a blocking Insulating layer 13A of each memory layer 13 and a channel layer 14, a liner layer 15, a barrier layer 16, a core insulating layer 17, and a capping pattern 18 of each channel structure 19 may be formed to have the same structures as those described above with reference to FIG. 1A. In an embodiment, as Illustrated in FIG. 2B, a tunnel insulating layer 13C, a data storage layer 13B, and a blocking insulating layer 13A of each memory layer 13 and a channel layer 14, a liner layer 15, a barrier layer 16, a core insulating layer 17, and a capping pattern 18 of each channel structure 19 may be formed to have the same structures as those described above with reference to FIG. 1B.

Referring to FIGS. 2A and 2B, the interconnection structures 131, 132, 133, 141, 142, and 143 may include contact plugs 131, 132, and 133 and lines 141, 142, and 143. The interconnection structures 131, 132, 133, 141, 142, and 143 may be formed in the first interlayer insulating layer 180. Although, in FIGS. 2A and 2B, the first interlayer Insulating layer 180 is Illustrated as one layer, the first Interlayer insulating layer 180 may include stacked Insulating layers.

The first contact plugs 131 may be coupled to respective capping patterns 18. The first contact plugs 131 may electrically connect the capping patterns 18 to the first lines 141 corresponding thereto. The second contact plugs 132 may be coupled to the first lines 141, and may electronically connect the first lines 141 to the second lines 142. The third contact plugs 133 may be coupled to the second lines 142, and may electronically connect the second lines 142 to the third lines 143. The second lines 142 may be used as bit lines electrically connected to the cell strings CS, and the doped semiconductor layer 100 may be used as a source layer electrically connected to the cell strings CS.

The first coupling structures 150 may be configured to electrically connect the cell chip C_CHIP to the peripheral circuit chip P_CHIP. The first coupling structures 150 may include contact plugs, lines, or combinations thereof. The first coupling structures 150 may be electrically connected to the third lines 143.

The peripheral circuit chip P_CHIP may include a substrate 200, at least one transistor TR, interconnection structures 231, 232, 233, 234, 241, 242, 243, and 244, second coupling structures 250, and a second interlayer insulating layer 280.

The transistor TR may include a gate electrode 220 and a gate insulating layer 210. The gate insulating layer 210 may be interposed between the substrate 200 and the gate electrode 220. The transistor TR may further include a junction in the substrate 200.

The interconnection structures 231, 232, 233, 234, 241, 242, 243, and 244 may include contact plugs 231, 232, 233, and 234 and lines 241, 242, 243, and 244. The interconnection structures 231, 232, 233, 234, 241, 242, 243, and 244 may be formed in the second interlayer insulating layer 280. Although, in FIGS. 2A and 2B, the second interlayer insulating layer 280 is illustrated as one layer, the second interlayer insulating layer 280 may include stacked insulating layers.

The fourth contact plugs 231 may be coupled to the gate electrode 220 or the junction of the transistor TR. The fourth lines 241 may be electrically connected to the fourth contact plugs 231. The fifth contact plugs 232 may electrically connect the fourth lines 241 to the fifth lines 242. The sixth contact plugs 233 may electrically connect the fifth lines 242 to the sixth lines 243. The seventh contact plugs 234 may electrically connect the sixth lines 243 to the seventh lines 244.

The second coupling structures 250 may be configured to electrically connect the cell chip C_CHIP to the peripheral circuit chip P_CHIP. The second coupling structures 250 may include a contact plug a line or a combination thereof. The second coupling structures 250 may be electrically connected to the seventh lines 244. The second coupling structures 250 may contact the first coupling structures 150 of the cell chip C_CHIP. Therefore, the cell chip C_CHIP and the peripheral circuit chip P_CHIP may be electrically connected to each other through the first and second coupling structures 150 and 250. For example, the first coupling structures 150 and the second coupling structures 250 may be coupled to each other, and the first interlayer insulating layer 180 and the second interlayer insulating layer 280 may be coupled to each other, thus enabling the cell chip C_CHIP to be connected to the peripheral circuit chip P_CHIP. By means of this process, a gate stack GST is disposed between the substrate 200 and the doped semiconductor layer 100.

After the above-described cell chip C_CHIP and peripheral circuit chip P_CHIP have been separately manufactured, they may be structurally coupled to each other through a coupling process.

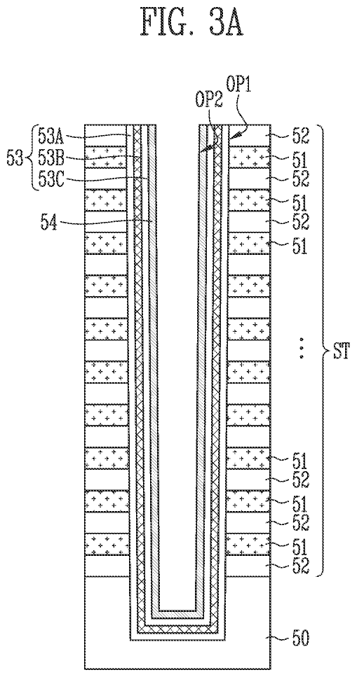

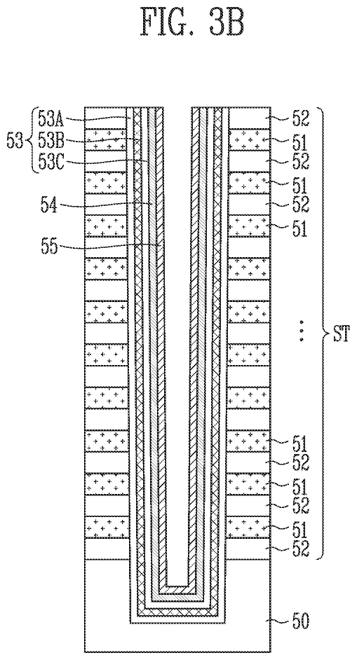

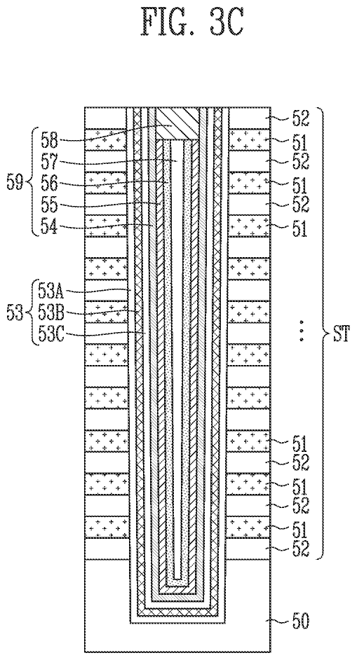

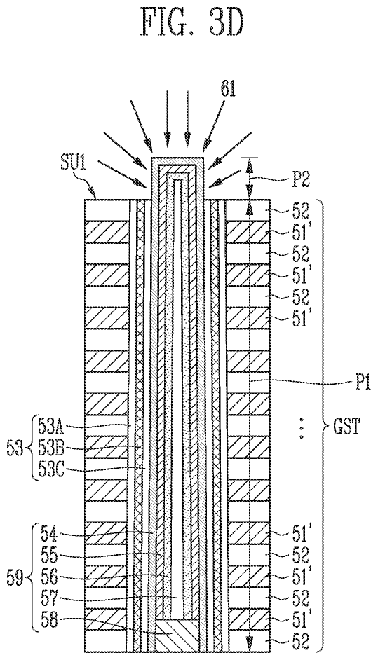

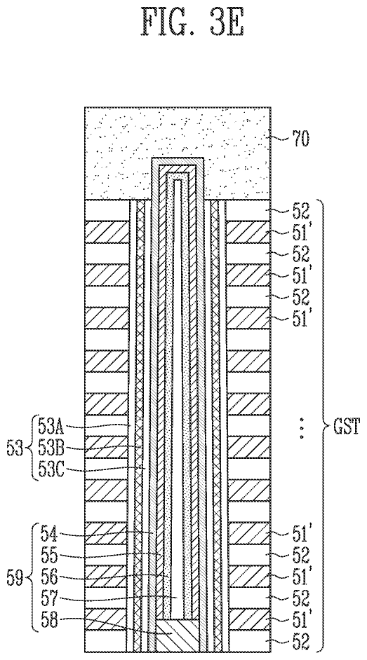

FIGS. 3A to 3E are schematic sectional views illustrating a method of manufacturing a semiconductor memory device according to an embodiment of the present invention disclosure. Hereinafter, repetitive descriptions identical to the above descriptions will be omitted.

Referring to FIG. 3A, an operation of alternately stacking first material layers 51 and second material layers 52 on top of one another on a substrate 50 may be performed. A structure in which the first material layers 51 and the second material layers 52 are alternately stacked on the substrate 50 is defined as a stacked body ST or simply a stack ST.

The substrate 50 may be formed of a material having an etch rate different from those of the first material layers 51 and the second material layers 52. For example, the substrate 50 may include silicon.

The first material layers 51 and the second material layers 52 may be made of different materials. In an embodiment, the first material layers 51 may be sacrificial layers, and the second material layers 52 may be insulating layers 12, as described above with reference to FIG. 1A. For example, each of the first material layers 51 may include a silicon nitride, and each of the second material layers 52 may include a silicon oxide. In the following drawings, although an embodiment in which the first material layers 51 are formed of sacrificial layers and the second material layers 52 are formed of insulating layers is illustrated, the present invention disclosure is not limited thereto. The material properties of the first material layers 51 and the second material layers 52 may be variously changed.

Next, a first opening OP1 passing through the stacked body ST may be formed. The first opening OP1 may expose the substrate 50 and pass through at least a portion of the substrate 50 as illustrated in FIG. 3A.

Then, a memory layer 53 may be formed in the first opening OP1. The memory layer 53 may include at least one of a blocking insulating layer 53A, a data storage layer 53B, and a tunnel insulating layer 53C.

Then, a channel layer 54 may be formed in the first opening OP1. When the memory layer 53 is formed first, the channel layer 54 may be formed in the memory layer 53. In this case, an outer surface of the channel layer 54 may contact the memory layer 53. For example, the outer surface of the channel layer 54 may contact an inner surface of the tunnel insulating layer 53C. The channel layer 54 may be formed to a thickness so that the first opening OP1 is not completely filled.

Referring to FIG. 3B, a liner layer 55 may be formed in a second opening OP2 illustrated in FIG. 3A. The liner layer 55 may include an insulating material such as an oxide or a nitride.

Referring to FIG. 3C, a barrier layer 56 may be formed in the liner layer 55. The barrier layer 56 may have the same structure and may be formed of the same material layer as the barrier layer 16 described with reference to FIG. 1A.

Next, a core insulating layer 57 may be formed in the barrier layer 56. The core insulating layer 57 may include an insulating material such as an oxide or a nitride.

Thereafter, respective portions of the core insulating layer 57, the liner layer 55, and the barrier layer 56 may be etched, and a capping pattern 58 may be formed on the core insulating layer 57, the barrier layer 56, and the liner layer 55. As a result, the capping pattern 58 may contact the channel layer 54. A structure including the channel layer 54, the liner layer 55, the barrier layer 56, the core insulating layer 57, and the capping pattern 58 may be defined as a channel structure 59.

Referring to FIG. 3D, the first material layers 51 may be replaced with third material layers 51′. Each of the third material layers 51′ may include at least one of a doped silicon layer, a metal silicide layer, and a metal layer. A structure in which the second material layers 52 and the third material layers 51′ are alternately stacked may be defined as a gate stack GST. The third material layers 51′ may have the same material properties as the conductive layers 11A, 11B, and 11C, described above with reference to FIGS. 1A and 1B.

When the first opening OP1 illustrated in FIG. 3A passes through a portion of the substrate 50, the channel layer 54 may include a first portion P1 penetrating the gate stack GST and a second portion P2 extending from the first portion P1 to protrude higher than the gate stack GST.

Then, the interconnection structures 131, 132, 133, 141, 142, and 143, the first interlayer insulating layer 180, and the first coupling structures 150, described above with reference to FIGS. 2A and 2B, are formed, and thus a preliminary cell chip may be provided. The peripheral circuit chip P_CHIP, described above with reference to FIGS. 2A and 2B, may be provided through a separate process. Thereafter, the preliminary cell chip and the peripheral circuit chip P_CHIP, described above with reference to FIGS. 2A and 2B, may be coupled to each other.

Next, an operation of selectively removing the substrate 50, illustrated in FIG. 3C, and an operation of selectively removing a portion of the memory layer 53 may be performed. In this way, the second portion P2 of the channel layer 54 may be exposed. By selectively removing the substrate 50 and the memory layer 53, the second portion P2 of the channel layer 54 may remain protruding higher than a first surface SU1 of the corresponding second material layer 52. The memory layer 53 may remain interposed between the gate stack GST and the channel layer 54.

Thereafter, a doped region may be formed in the protruding second portion P2 of the channel layer 54 by implanting conductive impurities 61 into the second portion P2 of the channel layer 54. In accordance with an embodiment of the present invention disclosure, the conductive impurities 61 may be blocked by the barrier layer 56. Accordingly, the embodiment of the present invention disclosure may improve a phenomenon in which the conductive impurities 61 are implanted into a location deviating from a target through void even if the void is formed in the core insulating layer 57.

In an embodiment, the process of implanting the conductive Impurities 61 may be performed after the substrate 50 illustrated in FIG. 3C has been removed, but before a portion of the memory layer 53 is removed. In this case, the channel layer 54 may be exposed by removing the portion of the memory layer 53 after the process of implanting the conductive impurities 61 has been performed.

Referring to FIG. 3E, a doped semiconductor layer 70 may be formed on the first surface SU1 of the corresponding second material layer 52. The doped semiconductor layer 70 may include at least one of n-type impurities and p-type impurities. In an embodiment, the doped semiconductor layer 70 may include n-type impurities. The doped semiconductor layer 70 may contact the second portion P2 of the channel layer 54.

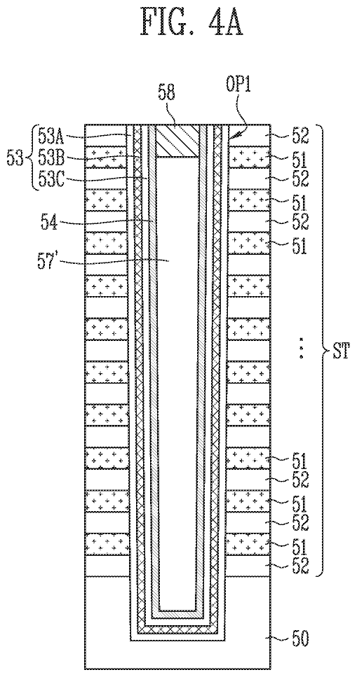

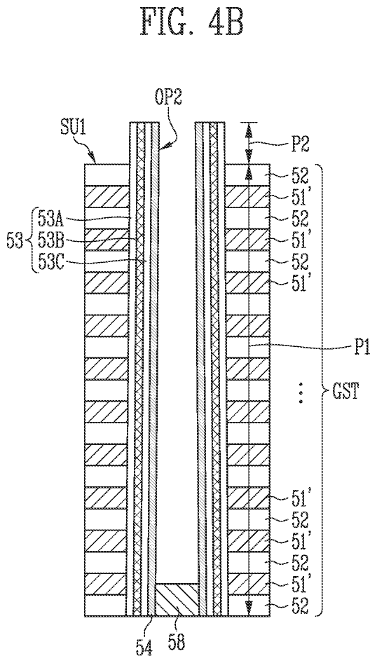

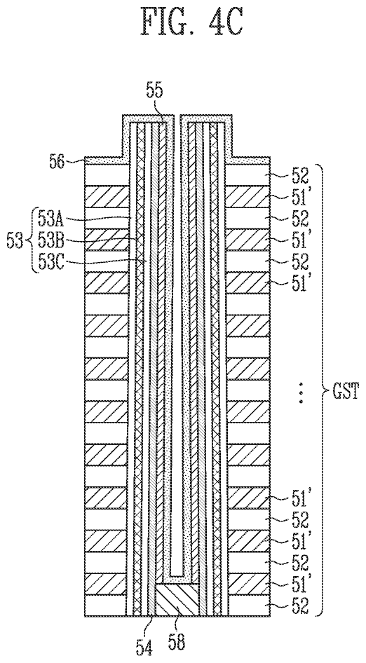

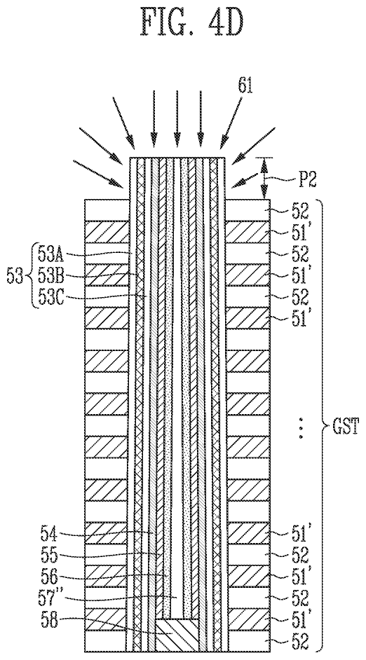

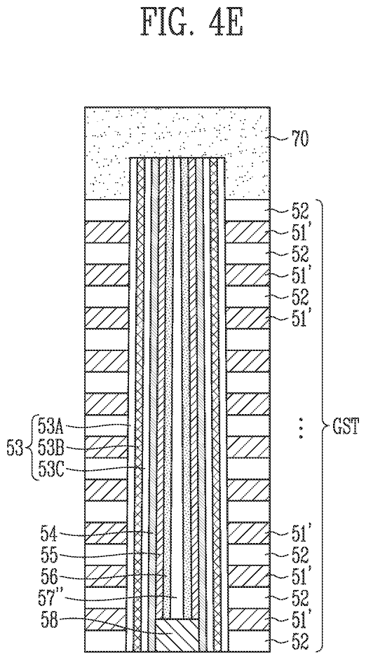

FIGS. 4A to 4E are schematic sectional views Illustrating a method of manufacturing a semiconductor memory device according to an embodiment of the present invention disclosure.

Referring to FIG. 4A, as described above with reference to FIG. 3A, the method may include an operation of forming a stacked body ST by alternately stacking first material layers 51 and second material layers 52 on a substrate 50, an operation of forming a first opening OP1 passing through the stacked body ST, an operation of forming a memory layer 53 in the first opening OP1, and an operation of forming a channel layer 54 in the memory layer 53. Thereafter, a first core insulating layer 57′ may be formed in the channel layer 54.

Next, an operation of etching a portion of the first core insulating layer 57′ and an operation of forming a capping pattern 58 on the first core insulating layer 57′ may be performed.

Referring to FIG. 4B, as described above with reference to FIG. 3D, a gate stack GST may be formed by replacing the first material layers 51 illustrated in FIG. 3A with third material layers 51′. A subsequent process of forming a preliminary cell chip is performed, as described above with reference to FIG. 3D, after which the preliminary cell chip may be coupled to the peripheral circuit chip P_CHIP, described above with reference to FIGS. 2A and 2B. Next, respective portions of the substrate 50, the memory layer 53, and the channel layer 54, illustrated in FIG. 4A, may be removed through a planarization process such as chemical mechanical polishing (CMP) so that the first core insulating layer 57′ is exposed. Thereafter, the remaining region of the substrate 50 illustrated in FIG. 4A may be selectively removed. In this way, a portion of the memory layer 53 and the second portion P2 of the channel layer 54 may be exposed. The second portion P2 of the channel layer 54 may remain protruding higher than the first surface SU1 of the corresponding second material layer 52. Thereafter, the first core insulating layer 57′ illustrated in FIG. 4A may be removed such that a second opening OP2 is formed in a central region of the channel layer 54.

Referring to FIG. 4C, a liner layer 55 may be formed in the second opening OP2 illustrated in FIG. 4B. The liner layer 55 may be formed in a hollow type along an inner wall of the channel layer 54. Thereafter, a barrier layer 56 may be formed to cover the gate stack GST and the second portion P2 of the channel layer 54. The barrier layer 56 may extend into the hollow-type liner layer 55.

Referring to FIG. 4D, a portion of the barrier layer 56 may be removed such that the gate stack GST and the memory layer 53 are exposed. Here, the capping pattern 58 may be exposed. The barrier layer 56 may remain to cover an inner wall of the liner layer 55. Thereafter, a second core insulating layer 57″ may be formed on the capping pattern 58.

Thereafter, a doped region may be formed in the protruding second portion P2 of the channel layer 54 by implanting conductive impurities 61 into the second portion P2 of the channel layer 54.

Referring to FIG. 4E, a doped semiconductor layer 70 contacting the channel layer 54 may be formed, as described above with reference to FIG. 3E.

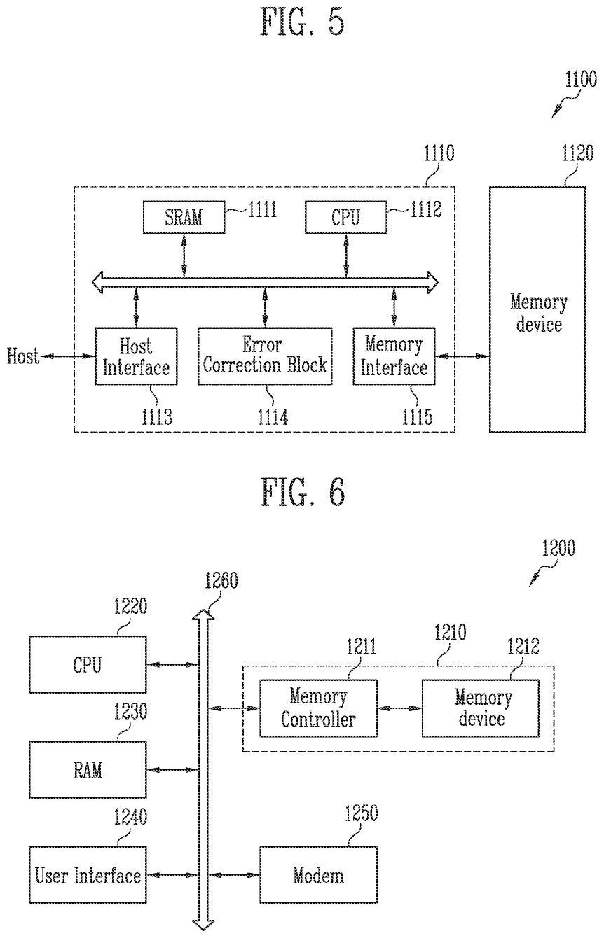

FIG. 5 is a simplified block diagram illustrating the configuration of a memory system according to an embodiment of the present invention disclosure.

Referring to FIG. 5, a memory system 1100 includes a memory device 1120 and a memory controller 1110.

The memory device 1120 may be a multi-chip package composed of a plurality of flash memory chips. The memory device 1120 may be a nonvolatile memory. Also, the memory device 1120 may have the structure, described above with reference to FIG. 1A to 2B, and may be manufactured based on the manufacturing method, described above with reference to FIGS. 3A to 4E. In an embodiment, the memory device 1120 may include a gate stack, and a channel structure disposed in the gate stack, wherein the channel structure may include a channel layer having a first portion penetrating the gate stack and a second portion extending from the first portion to protrude higher than the gate stack, a core insulating layer disposed in a central region of the channel structure, and a barrier layer disposed between the channel layer and the core Insulating layer. Since the structure of the memory device 1120 and the method of manufacturing the memory device 1120 are the same as those described above, detailed descriptions thereof will be omitted.

The memory controller 1110 may control the memory device 1120, and may include a static random access memory (SRAM) 1111, a central processing unit (CPU) 1112, a host interface 1113, an error correction block 1114, and a memory interface 1115. The SRAM 1111 may be used as a working memory of the CPU 1112, the CPU 1112 may perform overall control operations for data exchange of the memory controller 1110, and the host interface 1113 may be provided with a data Interchange protocol of a host coupled to the memory system 1100. The error correction block 1114 may detect errors included in data read from the memory device 1120, and may correct the detected errors. The memory interface 1115 may interface with the memory device 1120. The memory controller 1110 may further include a read only memory (ROM) or the like that stores code data for interfacing with the host.

The above-described memory system 1100 may be a memory card or a solid state drive (SSD) in which the memory device 1120 and the memory controller 1110 are combined with each other. For example, when the memory system 1100 is an SSD, the memory controller 1110 may communicate with an external device (e.g., host) through one of various interface protocols, such as a universal serial bus (USB), a multimedia card (MMC), a peripheral component interconnection-express (PCI-E), a serial advanced technology attachment (SATA), a parallel advanced technology attachment (PATA), a small computer system interface (SCSI), an enhanced small disk interface (ESDI), and an Integrated Drive Electronics (IDE).

FIG. 6 is a simplified block diagram illustrating the configuration of a computing system according to an embodiment of the present invention disclosure.

Referring to FIG. 6, a computing system 1200 may include a CPU 1220, a random access memory (RAM) 1230, a user interface 1240, a modem 1250, and a memory system 1210 which are electrically connected to a system bus 1260. When the computing system 1200 is a mobile device, it may further include a battery for supplying an operating voltage to the computing system 1200, and may further include an application chipset, an image processor, a mobile DRAM, etc.

The memory system 1210 may include a memory device 1212 and a memory controller 1211.

The memory controller 1211 may be implemented in the same manner as the memory controller 1110, described above with reference to FIG. 5.

The present invention disclosure may provide a semiconductor memory device, which has improved operational reliability. Further, the present invention disclosure may provide a semiconductor memory device, which enables a manufacturing process thereof to be simplified when the semiconductor memory device is manufactured.

What is claimed is:

1. A semiconductor memory device, comprising:
a gate stack; and
a channel structure disposed in the gate stack,
wherein the channel structure comprises:
a channel layer including a first portion penetrating the gate stack and a second portion extending from the first portion to protrude higher than the gate stack;
a core insulating layer disposed in a central region of the channel structure; and
a barrier layer disposed between the channel layer and the core insulating layer.

2. The semiconductor memory device according to claim 1, further comprising:
a doped semiconductor layer disposed to overlap the gate stack and the second portion of the channel layer.

3. The semiconductor memory device according to claim 1, wherein the second portion of the channel layer includes at least one of an n-type impurity and a p-type impurity.

4. The semiconductor memory device according to claim 1, wherein the barrier layer includes at least one of a metal layer and a metal nitride layer.

5. The semiconductor memory device according to claim 4, further comprising:
a liner layer disposed between the barrier layer and the channel layer.

6. The semiconductor memory device according to claim 1, wherein the barrier layer includes an insulating material different from an insulating material of the core insulating layer.

7. The semiconductor memory device according to claim 2, wherein:
the channel layer and the barrier layer are interposed between the core insulating layer and the doped semiconductor layer, and
the core insulating layer is spaced apart from the doped semiconductor layer by the channel layer and the barrier layer.

8. The semiconductor memory device according to claim 2, wherein:
the core insulating layer contacts the doped semiconductor layer, and
the channel layer and the barrier layer extend along a sidewall of the core insulating layer.

9. A method of manufacturing a semiconductor memory device, comprising:
forming a gate stack on a substrate;
forming an opening that passes through the gate stack and extends into the substrate;
forming a memory layer in the opening;
forming a channel layer in the memory layer;
forming a barrier layer in the channel layer;
forming a core insulating layer in the barrier layer;
removing the substrate such that the channel layer Includes a first portion penetrating the gate stack and a second portion extending from the first portion to protrude higher than the gate stack; and
implanting a conductive impurity into the second portion of the channel layer.

10. The method according to claim 9, further comprising:
removing the substrate, and etching a portion of the memory layer such that the second portion of the channel layer is exposed.

11. The method according to claim 10, further comprising:
forming a doped semiconductor layer overlapping the gate stack and the second portion of the channel layer.

12. The method according to claim 9, further comprising:
forming a liner layer between the barrier layer and the channel layer.

13. The method according to claim 9, further comprising:
forming a capping pattern on the core insulating layer by etching respective portions of the core insulating layer and the barrier layer.

14. The method according to claim 9, wherein the barrier layer includes at least one of a metal layer and a metal nitride layer.

15. The method according to claim 9, wherein the second portion of the channel layer includes at least one of an n-type impurity and a p-type impurity.

16. A method of manufacturing a semiconductor memory device, comprising:
forming a gate stack on a substrate;
forming a first opening that passes through the gate stack and extends into the substrate;
forming a memory layer in the first opening;
forming a channel layer in the memory layer, the channel layer including a first portion penetrating the gate stack and a second portion extending from the first portion to protrude higher than the gate stack;
forming a first core insulating layer in the channel layer;
removing respective portions of the substrate, the memory layer, and the channel layer such that the first core insulating layer is exposed;
forming a second opening by removing the first core insulating layer;
forming a barrier layer along a surface of the second opening; and
implanting a conductive impurity into the second portion of the channel layer.

17. The method according to claim 16, further comprising:
forming a liner layer between the barrier layer and the channel layer.

18. The method according to claim 16, further comprising:
forming a capping pattern on the first core insulating layer by etching respective portions of the first core Insulating layer and the barrier layer.

19. The method according to claim 16, wherein the barrier layer includes an insulating material different from an insulating material of the first core insulating layer.

20. The method according to claim 19, further comprising:
forming a doped semiconductor layer overlapping the gate stack and the second portion of the channel layer.
